(19) United States
(12) Patent Application Publication
(10) Pub. No.: US 2007/0289719 A1
(43) Pub. Date: Dec. 20, 2007

(54) Cooling apparatus and system thereof

(75) Inventors: Hung-Chun Chu, Taipei (TW); Chun-Chieh Wu, Taipei (TW)

Correspondence Address: BIRCH STEWART KOLASCH & BIRCH, PO BOX 747, FALLS CHURCH, VA, 22040-0747, US

(73) Assignee: ASUSTeK COMPUTER INC.

(21) Appl. No.: 11/802,374

(22) Filed: May 22, 2007

(30) Foreign Application Priority Data
May 24, 2006 (TW) 95118510

(51) Int. Cl. H05K 7/20

(52) U.S. Cl. 165/80.4; 361/699; 165/104.33

(57) ABSTRACT

A cooling apparatus for dissipating a heat from a heat source by a fluid includes a cooling fin set, a water-cooling pipe, and a heat tube. The water-cooling pipe and the heat tube are penetrating through the cooling fin set. The cooling apparatus further includes a base, and the heat tube is coupled on the base for supporting the cooling pipe and the cooling fins. The cooling pipe further includes an influent combined with the base. A part of the heat from the fluid is transferred to the heat tube from the base and transferred to the cooling fin set from the heat tube and then dissipated. Another part of the heat is transferred to the cooling fin set from the water-cooling pipe. A cooling system with the cooling apparatus is also disclosed.

### RELATED APPLICATIONS

This application claims priority to Taiwan Application Serial Number 95118510, filed May 24, 2006, which is herein incorporated by reference.

### BACKGROUND

1. Field of Invention

The present invention relates to a cooling apparatus and system. More particularly, the present invention relates to a computer cooling apparatus and system.

2. Description of Related Art

Information technology and computer industrial are highly developed now. The semiconductor manufacturing process has been highly improved. The design of the semiconductor becomes more complicated due to the function requirement is more serious day by day. For example, the electric circuit layout of the central processing unit (CPU) is getting more complicated to provide more functions for users and application softwares. The new generation CPU provides powerful function and performance but the powerful CPU also generates some undesirable problems. A serious problem is the new CPU with a complicated circuit consumes a lot of power, which increases CPU temperature. The high temperature leads the working system unstable. In general, lower working temperature allows CPU to work more stably. That is to say, if the computer temperature can be lowered, the performance thereof can be higher. If the temperature is too high, the performance and stability will go down and even the system may crash.

In practice, the computer needs a high power fan to exhaust heat inside. The high power fan may cause noises while it is working. The noises not only come from the fan itself but also come from magnetic poles, revolutions, blades of the fan, and combinations thereof.

For the foregoing reasons, there is a need to cool the computer by a high efficiency cooling apparatus.

### SUMMARY

It is therefore an objective of the present invention to provide a cooling apparatus and system to improve the heat dissipating efficiency of a computer.

It is another objective of the present invention to provide a cooling apparatus to install at different places by a base.

It is still another objective of the present invention to provide a cooling apparatus to reduce the number of fans.

In accordance with the foregoing and other objectives of the present invention, the invention provides a cooling apparatus to dissipate a heat. The cooling apparatus includes a cooling fin set consisting of several cooling fins, a water-cooling pipe penetrating through the cooling fin set, and a heat tube penetrating through the cooling fin set. The heat tube is an U-tube. The water-cooling pipe is a circuitous pipe penetrating through the cooling fin set back and forth. The material of the water-cooling pipe, the cooling fin set, and the heat tube is a high thermal conductivity metal.

The invention also provides a cooling apparatus to dissipate a heat. The cooling apparatus includes a base, a cooling fin set consisting of several cooling fins, a water-cooling pipe penetrating through the cooling fin set, and a heat tube penetrating through the cooling fin set and combined together on the base. The water-cooling pipe further includes an influent, and the base further includes a semicircular base bottom spread with a heat-transfer paste, wherein the semicircular base bottom is coupled with the influent. The material of the water-cooling pipe, the cooling fin set, the heat tube, and the influent is a high thermal conductivity metal. The heat tube is an U-tube. The water-cooling pipe is a circuitous pipe penetrating through the cooling fin set back and forth. The base is installed on a heat sink.

The invention further provides a cooling system. The cooling system includes a cooling apparatus and a cycle apparatus. The cooling apparatus includes a base, a cooling fin set consisting of several cooling fins, a water-cooling pipe penetrating through the cooling fin set, and a heat tube penetrating through the cooling fin set and coupled on the base. The cycle apparatus includes a fluid driver, a water-cooling heat exchanger disposed on a heat source, and several pipes to connect the water-cooling pipe, the fluid driver, and the water-cooling heat exchanger to provide a fluid to dissipate a heat generated from the heat source. The water-cooling pipe further includes an influent, and the base further includes a semicircular base bottom spread with a heat-transfer paste, wherein the semicircular base bottom is coupled with the influent. The material of the water-cooling pipe, the coiling fin set, the heat tube, and the influent is a high thermal conductivity metal. The base is installed on a heat sink. The fluid driver comprises a water tank and a water pump. The heat tube is an U-tube. The water-cooling pipe is a circuitous pipe penetrating through the cooling fin set back and forth. The heat source is an electric device. The electric device is a southbridge chip or a northbridge chip. The cooling system further includes a fan installed near the cooling apparatus to improve an efficiency of the cooling apparatus.

As embodied and broadly described herein, the invention provides a cooling apparatus and system to improve the heat dissipating efficiency of computer and reduce the number of fans in the computer.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic diagram according to a first embodiment of a cooling apparatus of this invention;

FIG. 2 is a schematic diagram according to a second embodiment of the cooling apparatus of this invention;

FIG. 3 is a schematic diagram according to a third embodiment of the cooling apparatus of this invention;

FIG. 4 is an exploded diagram according to the third embodiment of this invention;

FIG. 5 is a schematic diagram according to an embodiment of a cooling system of this invention; and

FIG. 6 is a schematic diagram according to another embodiment of the cooling system of this invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

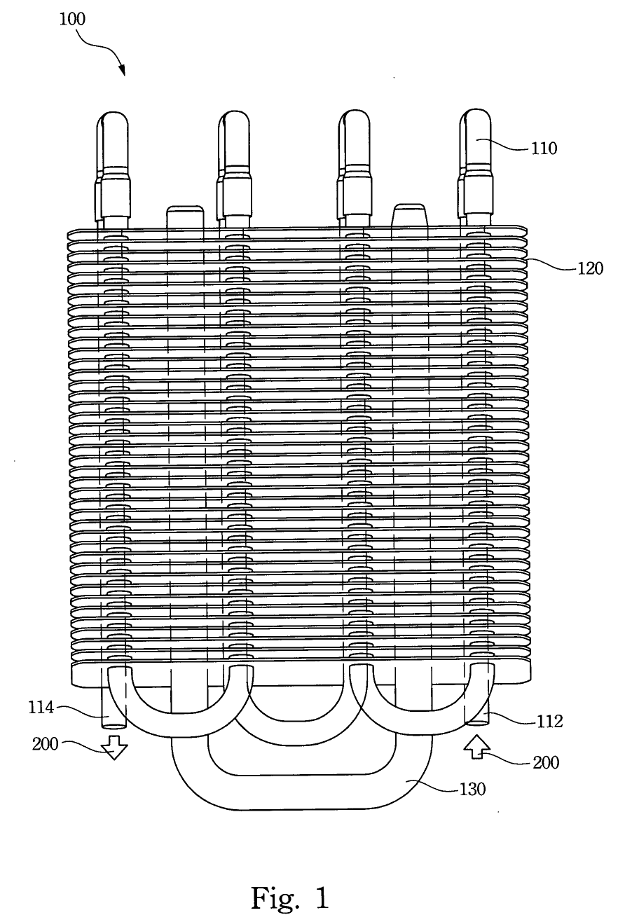

FIG. 1 illustrates a schematic diagram according to a first embodiment of a cooling apparatus. The cooling apparatus 100 dissipating a heat by a fluid 200 includes a cooling fin set 120 consisting of a plurality of cooling fins, a water-cooling pipe 110, and a heat tube 130. The water-cooling pipe 110 is a circuitous pipe penetrating through the cooling fin set 120 back and forth. The heat tube 130 is an U-tube penetrating through the cooling fin set 120 and combined with the water-cooling pipe 110, the cooling fin set 120, and the heat tube 130. The water-cooling pipe 110 has an inlet 112 and an outlet 114. The material of the water-cooling pipe 110, the cooling fin set 120, and the heat tube 130 is a high thermal conductivity metal. The high thermal conductivity metal may be a copper (Cu) or an aluminum (Al).

The fluid 200 is introduced into the water-cooling pipe 110 from the inlet 112 and passes through the circuitous water-cooling pipe 110 then flows out through the outlet 114. The heat of the fluid 200 is transferred to the cooling fin set 120 via water-cooling pipe 110. The heat tube 130 may further improve the heat dissipating efficiency.

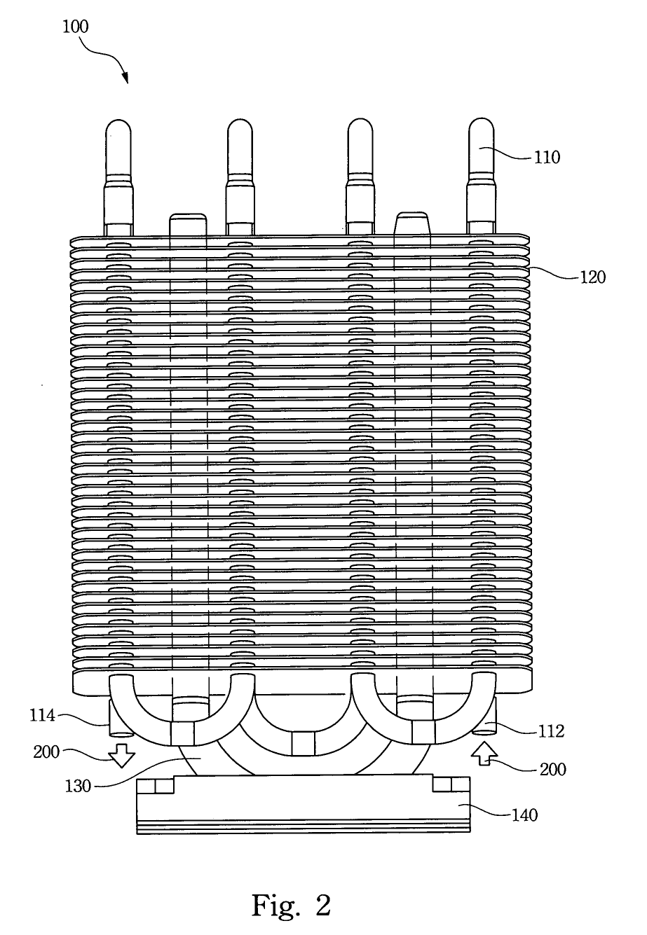

FIG. 2 illustrates a second embodiment according to the cooling apparatus. The cooling apparatus 100 further includes a base 140. The heat tube 130 is coupled on the base 140 to support the cooling fin set 120 and the water-cooling pipe 110. The heat tube 130 may be soldered on the base 140 by a tin solder. The fluid 200 with high temperature flows into the water-cooling pipe 110 from the inlet 112 and passes through the circuitous water-cooling pipe 110 then flows out through the outlet 114. The cooling apparatus 100 may dissipate the heat by both water-cooling and air-cooling. The water-cooling pipe 110 and the cooling fin set 120 may stand on the base 140 by the support of the heat tube 130. Thus the cooling apparatus 100 may be installed on different places to cool the computer.

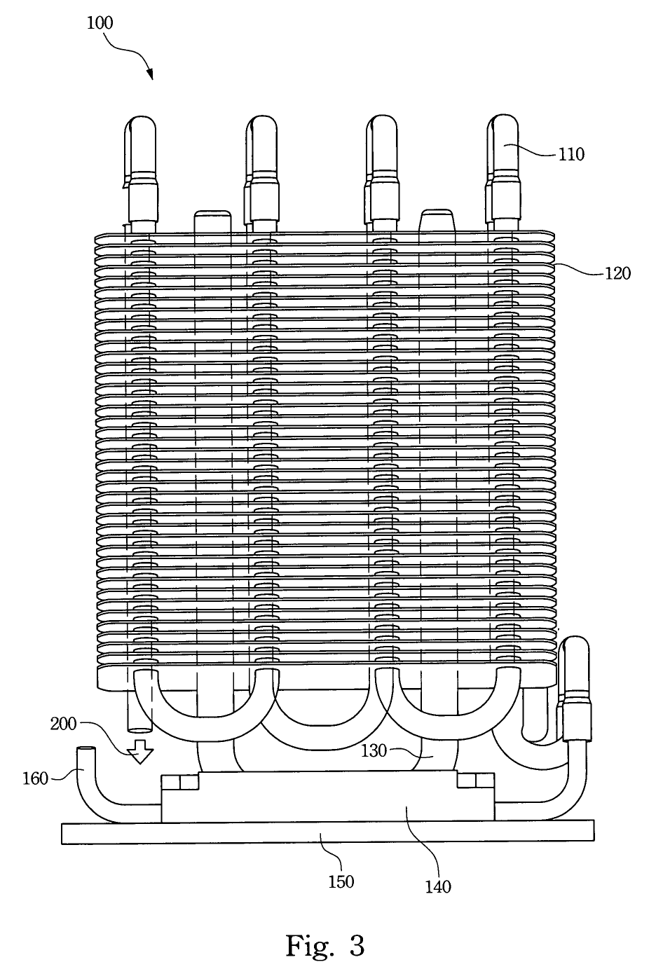

Referring to FIG. 3, the cooling apparatus 100 is installed on a heat sink 150. The water-cooling pipe 110 further includes an influent 160. The influent 160 may be a copper tube. The base 140 of the cooling apparatus 100 is coupled on the influent 160. The fluid 200 flows into the water-cooling pipe 110 through the influent 160. A part of the heat from the fluid 200 is transferred to the heat tube 130 from the base 140 and transferred to the cooling fin set 120 from the heat tube 130 and then dissipated. Another part of the heat is transferred to the cooling fin set 120 from the water-cooling pipe 110 and then dissipated.

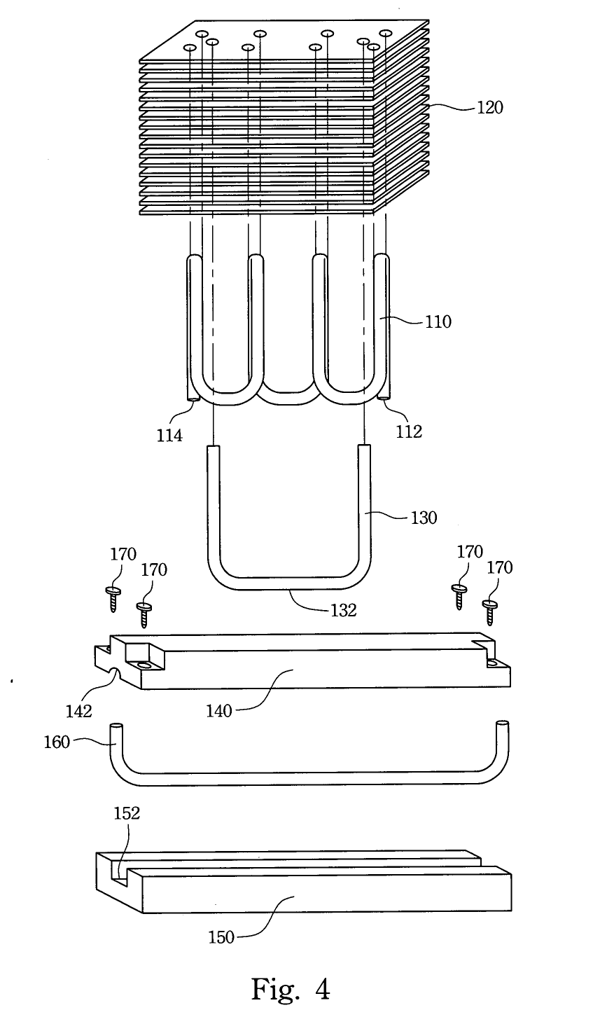

FIG. 4 illustrates an exploded diagram of the cooling apparatus in FIG. 3. The heat sink 150 has a fillister 152, and the influent 160 is disposed in the fillister 152. The influent 160 may be coupled with the fillister 152 by the tin solder. The base 140 further comprises a semicircular base bottom 142 spread with a heat-transfer paste. The semicircular base bottom 142 is coupled with the influent 160 on the heat sink 150. The heat tube 130 has a heat tube bottom 132 coupled with the base 140 by the tin solder. The base 140 may be fixed on the heat sink 150 by a plurality of screws 170. A part of the heat from the fluid 200 is transferred to the base 140 through the influent 160 and the base bottom 142 spread with the heat-transfer paste, then transferred to the heat tube 130. The part of the heat is dissipated to the air from the cooling fin set 120 via the heat tube 130. An air-cooling flow path of the cooling apparatus 100 is disclosed above. The fluid 200 flows into the inlet 112 through the influent 160, then passes through the circuitous water-cooling pipe 110 and flows out through the outlet 114. Another part of the heat from the fluid 200 is transferred to the cooling fin set 120 via the water-cooling pipe 110, then dissipated to the air from the cooling fin set 120. A water-cooling flow path of the cooling apparatus 100 is disclosed above.

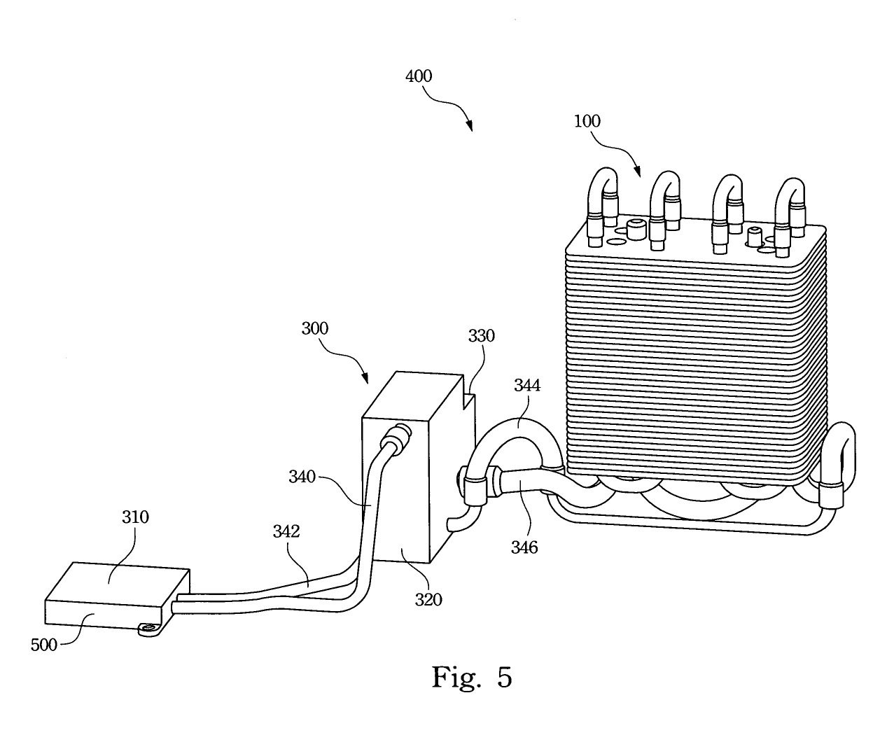

FIG. 5 illustrates a schematic diagram according to an embodiment of a cooling system. The cooling system 400 includes the cooling apparatus 100 and a cycle apparatus 300. The cycle apparatus 300 includes a water-cooling heat exchanger 310 disposed on a heat source 500, a water tank 320 with a water pump 330, and a plurality of water pipes 340, 342, 344, and 346 for connecting the cycle apparatus 300 and the cooling apparatus 100 to provide the fluid 200. The water tank 320 and the water pump 330 are combined together as a fluid driver. The heat source 500 is an electric device, for example, the heat source 500 may be a southbridge chip. The fluid 200 is pumped out to the water pipe 340 from the water tank 320 by the water pump 330 then flows to the water-cooling heat exchanger 310 disposed on the heat source 500 by gravity. The fluid 200 takes away the heat generated by the heat source 500 and returns to the water tank 320 through the water pipe 342. Then the fluid 200 flows to the cooling apparatus 100 for cooling through the water pipe 344 and returns to the water tank 320 through the pipe 346 to proceed next cycle.

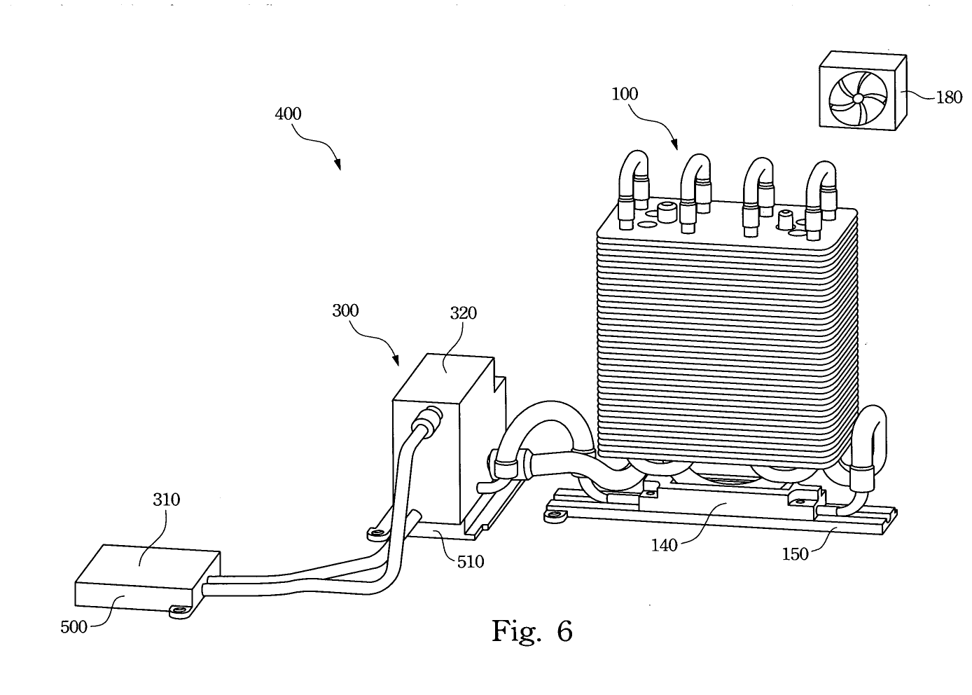

FIG. 6 illustrates another embodiment of the cooling system. The cooling system 400 may have different ramifications. For example, the cooling apparatus 100 may be fixed on the heat sink 150 by the base 140. The cooling apparatus 100 may also be installed at different places by the base 140. The water-cooling heat exchanger 310 may be disposed on the heat source 500. The water tank 320 may be placed on another heat source 510. The heat source 500 may be the southbridge chip, and the heat source 510 may be a northbridge chip. The cooling system 400 may further include a fan 180 disposed near the cooling apparatus 100 to improve the heat dissipating efficiency of the cooling apparatus 100.

The cooling apparatus of the invention may use both water-cooling and air-cooling to dissipate the heat and improve the heat dissipating efficiency especially in a computer system. The cooling apparatus may be installed at different places by the base so the applicability and flexibility of the cooling apparatus can be increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A cooling apparatus, comprising:
a cooling fin set comprising a plurality of cooling fins;
a water-cooling pipe penetrating through the cooling fin set; and
a heat tube penetrating through the cooling fin set.

2. The cooling apparatus of claim 1, wherein the heat tube is an U-tube.

3. The cooling apparatus of claim 1, wherein the water-cooling pipe is a circuitous pipe penetrating through the cooling fin set back and forth.

4. The cooling apparatus of claim 1, wherein a material of the water-cooling pipe, the cooling fin set, and the heat tube is a high thermal conductivity metal.

5. A cooling apparatus, comprising:
a base;
a cooling fin set comprising a plurality of cooling fins;
a water-cooling pipe penetrating through the cooling fin set; and
a heat tube penetrating through the cooling fin set and combined on the base.

6. The cooling apparatus of claim 5, wherein the water-cooling pipe further comprises an influent, the base further comprises a semicircular base bottom spread with a heat-transfer paste, wherein the semicircular base bottom is coupled with the influent.

7. The cooling apparatus of claim 6, wherein a material of the water-cooling pipe, the cooling fin set, the heat tube, and the influent is a high thermal conductivity metal.

8. The cooling apparatus of claim 5, wherein the heat tube is an U-tube.

9. The cooling apparatus of claim 5, wherein the water-cooling pipe is a circuitous pipe penetrating through the cooling fin set back and forth.

10. The cooling apparatus of claim 5, wherein the base is installed on a heat sink.

11. A cooling system, comprising:
a cooling apparatus, comprising:
a base;
a cooling fin set comprising a plurality of cooling fins;
a water-cooling pipe penetrating through the cooling fin set;
a heat tube penetrating through the cooling fin set, and coupled on the base; and
a cycle apparatus, comprising:
a fluid driver;
a water-cooling heat exchanger, disposed on a heat source; and
a plurality of water pipes to connect the water-cooling pipe, the fluid driver, and the water-cooling heat exchanger to provide a fluid to dissipate a heat generated from the heat source.

12. The cooling system of claim 11, wherein the water-cooling pipe further comprises an influent, the base further comprises a semicircular base bottom spread with a heat-transfer paste, wherein the semicircular base bottom is coupled with the influent.

13. The cooling system of claim 12, wherein a material of the water-cooling pipe, the cooling fin set, the heat tube, and the influent is a high thermal conductivity metal.

14. The cooling system of claim 11, wherein the base is installed on a heat sink.

15. The cooling system of claim 11, wherein the fluid driver comprises a water tank and a water pump.

16. The cooling system of claim 11, wherein the heat tube is an U-tube.

17. The cooling system of claim 11, wherein the water-cooling pipe is a circuitous pipe penetrating through the cooling fin set back and forth.

18. The cooling system of claim 11, wherein the heat source is an electric device.

19. The cooling system of claim 18, wherein the electric device is a southbridge chip or a northbridge chip.

20. The cooling system of claim 11, wherein the cooling system further comprises a fan disposed near the cooling apparatus to improve an efficiency of the cooling apparatus.
